(19) United States
(12) Patent Application Publication
(10) Pub. No.: US 2007/0141857 A1
(43) Pub. Date: Jun. 21, 2007

(54) Target designs and related methods for enhanced cooling and reduced deflection and deformation

(76) Inventors: Susan D. Strothers, Spokane, WA (US); Werner H. Hort, Cranberry, PA (US); Frederick K. McNeil, Alamo, CA (US)

Correspondence Address: BINGHAM MCCUTCHEN LLP, Three Embarcadero Center, San Francisco, CA, 94111-4067, US

(21) Appl. No.: 10/531,763

(22) PCT Filed: Oct. 24, 2003
(86) PCT No.: PCT/US03/33879

§ 371 Date: Jul. 27, 2006

Related U.S. Application Data
(60) Provisional application No. 60/421,478, filed on Oct. 24, 2002.

(51) Int. Cl. H01L 21/31

(52) U.S. Cl. 438/778

(57) ABSTRACT

A sputtering target is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature increases the effective surface area of the core backing component. Additional sputtering targets comprises: a) an integrated target surface component and core backing component, wherein the surface component and the backing component comprise the same target material or a material gradient; and b) at least one surface area feature that is on or integrated into the core backing component, wherein the surface area feature increases the effective component of the core backing component. Methods of forming a sputtering target are also described that comprise: a) providing a target surface component comprising a surface material; b) providing a core backing component comprising a backing material and having a coupling surface and a back surface; c) providing at least one surface area feature coupled to or located in the back surface of the core backing plate, wherein the surface area feature increases the effective surface area of the core backing plate or providing at least one surface area feature coupled to or located in the coupling surface of the core backing component, wherein the surface area feature increases the effective surface area of the core backing component; and d) coupling the surface target material to the coupling surface of the core backing material.

This application claims priority to U.S. Provisional Application Ser. No. 60/421478 filed on Oct. 24, 2002, which is commonly owned and incorporated herein in its entirety.

### FIELD OF THE SUBJECT MATTER

The field of the subject matter is design and use of sputtering targets that have enhanced cooling and can reduce deflection of sputtered materials.

### BACKGROUND OF THE SUBJECT MATTER

Electronic and semiconductor components are used in ever-increasing numbers of consumer and commercial electronic products, communications products and data-exchange products. Examples of some of these consumer and commercial products are televisions, computers, cell phones, pagers, palm-type or handheld organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, modified and improved.

In order to improve the process of depositing a layer of material, the surface and/or material composition must be measured, quantified and defects or imperfections detected. In the case of the deposition of a layer or layers of material, its not only the actual layer or layers of material that should be monitored but also the material and surface of that material that is being used to produce the layer of material on a substrate or other surface that should be monitored. For example, when depositing a layer of metal onto a surface or substrate by sputtering a target comprising that metal, the target must be monitored for uneven wear, target deformation, target deflection and other related conditions. Uneven wear of a sputtering target is inevitable, a function of the magnet design and will reduce the lifetime of the target, and in some cases result in little or no deposition, of the metal on the surface of a substrate.

Gardell et al. (U.S. Pat. No. 5,628,889) discloses a high-power capacity magnetron cathode with an independent cooling system for the magnet array support plate. In Gardell, a horizontal magnet array fluid control surface is physically attached to the magnet array support plate. The fluid control surface or device is not integrated into the materials of the support plate, the magnet array or the cathode materials. Therefore, there are more working parts, additional layers of complexity in the design and use of the magnetron cathode, and additional work for workers who handle repair and replacement of parts.

During conventional manufacturing and/or use of either electronic and/or semiconductor components, the wear of materials and targets cannot be easily checked, because such checks either require that the operation be interrupted, or that an experienced operator be at hand or on an equipment monitoring schedule, both of which are costly. This often results in scheduled (rather than on demand) replacement of such materials, which again leads to costly waste of material, especially if the material is expensive to obtain or replace or if the material is not compromised in the first place.

Prior Art FIGS. 1 and 2 show a new conventional target 100 and the same target 200, which has shown an uneven wear pattern 220 after a period of use. Conventional targets are also subject to bowing or deformation, shown in the warpage profiles of FIGS. 3 and 4 (and related FIGS. 8 and 9, which are described in the Examples section), when the target is heated to the point where bowing and/or deformation can occur and when the cooling system or method is not utilized effectively or is not efficient.

To this end, it would be desirable to develop and utilize a cooling system that will a) maximize the cooling efficiency of both a conventional target and a monolithic target by maximizing the contact area for the substance used to cool the target; b) reduce the deformation of the target in service; c) increase the rigidity of the target configuration, which leads to additional resistance to deformation and warpage/bowing; d) provide ease of use as compared to conventional systems; e) minimize unwanted deflection of sputtered atoms and molecules; and f) be effective for both monolithic (unibody design), three-dimensional and conventional sputtering targets that have a target coupled to a backing plate.

### SUMMARY OF THE INVENTION

A sputtering target is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature increases the effective surface area of the core backing component.

Another sputtering target is described herein that comprises: a) a target surface component comprising a target material; b) a core backing component having a coupling surface and a back surface, wherein the coupling surface is coupled to the target surface material; and c) at least one surface area feature coupled to or located in the back surface of the core backing component, wherein the surface area feature comprises a subtractive feature, an additive feature or a combination thereof.

Yet another contemplated sputtering target and/or sputtering target assembly comprises: a) an integrated target surface component and core backing component, wherein the surface component and the backing component comprise the same target material; and b) at least one surface area feature that is on or integrated into the core backing component, wherein the surface area feature increases the effective component of the core backing component.

In other contemplated embodiments, a sputtering target and/or sputtering target assembly comprises: a) an integrated target surface component and core backing component, wherein the sputtering target comprises a target material gradient; and b) at least one surface area feature that is located on or integrated into the core backing component, wherein the surface area feature increases the effective component of the core backing component.

Methods of forming a sputtering target are also described that comprises: a) providing a target surface component comprising a surface material; b) providing a core backing component comprising a backing material and having a coupling surface and a back surface; c) providing at least one surface area feature coupled to or located in the back surface of the core backing plate, wherein the surface area feature increases the effective surface area of the core backing plate; and d) coupling the surface target material to the coupling surface of the core backing material.

Additional methods of forming a sputtering target are also described that comprises: a) providing a target surface component comprising a surface material; b) providing a core backing component comprising a backing material and having a coupling surface and a back surface; c) providing at least one surface area feature coupled to or located in the coupling surface of the core backing component, wherein the surface area feature increases the effective surface area of the core backing component; and d) coupling the surface target material to the coupling surface of the core backing component.

### BRIEF DESCRIPTION OF THE FIGURES

FIG. 1 shows a photo of conventional sputtering target assembly.

FIG. 2 shows a photo of a non-uniformly worn conventional sputtering target assembly.

FIG. 3 shows warpage of a sputtering target assembly.

FIG. 4 shows warpage of a sputtering target assembly.

FIG. 5 shows several contemplated core backing component configurations.

FIG. 6 shows several contemplated core backing component configurations.

FIG. 7 shows an expanded view of a contemplated core backing component configuration.

FIG. 8 shows an erosion profile of a contemplated embodiment.

FIG. 9 shows an erosion profile of a side-cooled sputtering target assembly.

FIG. 10 shows a stress-strain curve for a CuCr core backing component.

FIG. 11 shows comparison erosion profiles for contemplated embodiments.

FIG. 12 shows comparison erosion profiles for contemplated embodiments.

FIG. 13 shows comparison erosion profiles for contemplated embodiments.

FIG. 14 shows comparison erosion profiles for contemplated embodiments.

FIG. 15 shows comparison erosion profiles for contemplated embodiments.

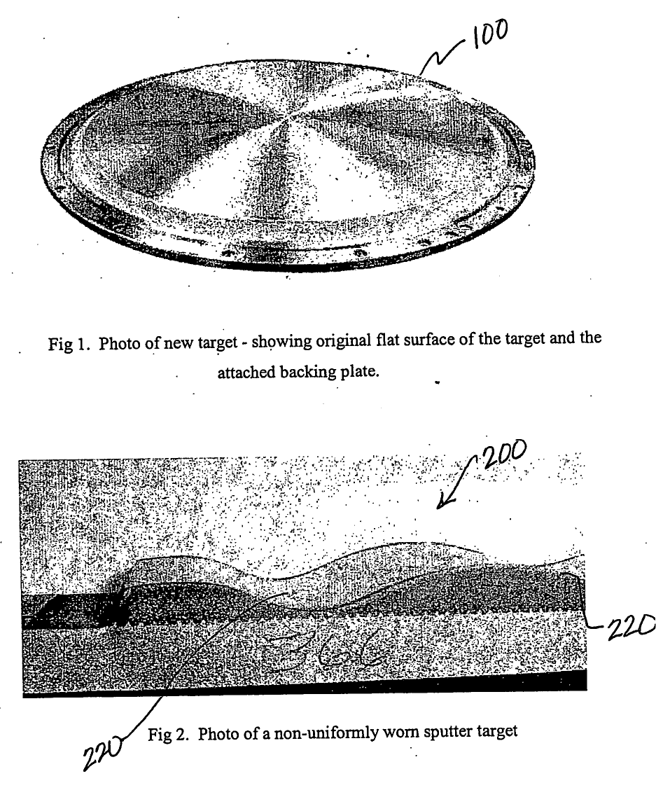

### DETAILED DESCRIPTION

A sputtering target and related cooling system has been developed and is described herein that a) maximizes the cooling efficiency of both a conventional target and a monolithic target by maximizing the contact area for the substance used to cool the target; b) reduces the deformation of the target in service; c) increases the rigidity of the target configuration, which leads to additional resistance to deformation and warpage/bowing; d) provides ease of use as compared to conventional systems; e) minimizes unwanted deflection of sputtered atoms and molecules; and f) is effective for both monolithic (unibody design), three-dimensional and conventional sputtering targets that have a target coupled to a backing plate.

To this end, a sputtering target and/or sputtering target assembly comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature increases the effective surface area of the core backing component. In some embodiments, the target surface component and the core backing component comprise the same material as the target material.

Another contemplated sputtering target and/or sputtering target assembly comprises: a) an integrated target surface component and core backing component, wherein the surface component and the backing component comprise the same target material; and b) at least one surface area feature that is on or integrated into the-core backing component, wherein the surface area feature increases the effective component of the core backing component. In related contemplated embodiments, a sputtering target and/or sputtering target assembly comprises: a) an integrated target surface component and core backing component, wherein the sputtering target comprises a target material gradient; and b) at least one surface area feature that is located on or integrated into the core backing component, wherein the surface area feature increases the effective component of the core backing component.

Another sputtering target and/or sputtering target assembly is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature comprises a subtractive feature, an additive feature or a combination thereof. In some embodiments, the target surface component and the core backing component comprise the same material as the target material. In yet other embodiments, the target surface component and the core backing component are coupled such that they form a monolithic sputtering target and/or sputtering target assembly.

Sputtering targets and sputtering target assemblies contemplated herein comprise any suitable shape and size depending on the application and instrumentation used in the PVD process. Sputtering targets contemplated herein also comprise a target surface component and a core backing component (which can include a backing plate), wherein the target surface component is coupled to the core backing component through and/or around a gas chamber or gas stream. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. The target surface material and core backing material may generally comprise the same elemental makeup or chemical composition/component, or the elemental makeup and chemical composition of the target surface material may be altered or modified to be different than that of the core backing material. In several embodiments, the target surface material and the core backing material comprise the same elemental makeup and chemical composition. As mentioned, the term “coupled” may mean that there is a bond force or adhesive force between the constituents of the sputtering target and/or sputtering target assembly, such that the sputtering target and/or sputtering target assembly is monolithic.

The target surface component is that portion of the target that is exposed to the energy source at any measurable point in time and is also that part of the overall target material that is intended to produce atoms and/or molecules that are desirable as a surface coating. The target surface material comprises a front side surface and a back side surface. The front side surface is that surface that is exposed to the energy source and is that part of the overall target material that is intended to produce atoms and/or molecules that are desirable as a surface coating. The back side surface is that surface that is coupled to the core backing component. The target surface component comprises a target material and that material may be any material that is suitable for forming a sputtering target. In some embodiments, the target surface component comprises a three-dimensional target surface, such as a target surface that is concave, convex or has some other unconventional shape. It should be understood that the target surface component, no matter what the shape of the component is, is the portion of the target that is exposed to the energy source at any measurable point in time and is also that part of the overall target material that is intended to produce atoms and/or molecules that are desirable as a surface coating.

The core backing material is designed to provide support for the target surface component and material and to possibly provide additional atoms in a sputtering process or information as to when a target's useful life has ended. For example, in a situation where the core backing material comprises a material different from that of the original target surface material, and a quality control device detects the presence of core material atoms in the space between the target and the wafer, the target may need to be removed and retooled or discarded altogether because the chemical integrity and elemental purity of the metal coating could be compromised by depositing undesirable materials on the existing surface/wafer layer.

In a more specific example, a sensing/sensor device and/or method outlined above, among others, a sensing/sensor system has been designed that utilizes a change in the pressure or flow of a gas to notify the operator of wear and/or deterioration of a surface or material. Specifically, a gas at a particular pressure is contained in a space adjacent to the material. When the material wears down or deteriorates enough to open up the space where the gas is contained, there is a change in the pressure of the gas resulting in a signal or notification to the operator. The change in pressure of the gas can alert the operator of material wear and/or surface deterioration in several ways, including by setting off an alarm system, light or other type of signal, by automatically shutting down the system or by generating a message to the operator.

In some embodiments, it would also be ideal to include a sensing system that would a) comprise a simple device/apparatus and/or mechanical setup and a simple method for determining wear, wear-out and/or deterioration of a surface or material; b) would notify the operator when maintenance is necessary, as opposed to investigating the quality of the material on a specific maintenance schedule; and c) would reduce and/or eliminate material waste by reducing and/or eliminating premature replacement or repair of the material. Devices and methods of this type are described in PCT Application Serial No.: (not yet assigned) which was filed on Sep. 12, 2003 and claims priority to U.S. Provisional Application Ser. No. 60/410540, which was filed on Sep. 12, 2002, both of which are commonly-owned and incorporated herein in their entirety.

The core backing component may comprise any material that is suitable for use in a sputtering target. The core backing component comprises a coupling surface that is designed to couple to the back surface of the target surface component. The core backing component also comprises a back surface that is designed to form the back of the sputtering target assembly, wherein the sputtering target assembly comprises a target surface component and a core backing component. In some embodiments, the core backing component comprises a backing plate.

Sputtering targets may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, conductive monomers, dielectric materials, hardmask materials and any other suitable sputtering material.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, thorium or a combination thereof. More preferred metals include copper, aluminum, tungsten, titanium, cobalt, tantalum, magnesium, lithium, silicon, manganese, iron or a combination thereof Most preferred metals include copper, aluminum and aluminum-based materials, tungsten, titanium, zirconium, cobalt, tantalum, niobium or a combination thereof

Examples of contemplated and materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer of aluminum onto surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, tantalum, tin, zinc, lithium, manganese, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof.

The core backing material and/or the target surface material constituents may be provided by any suitable method, including a) buying the core material and/or the surface material constituents from a supplier; b) preparing or producing the core material and/or the surface material constituents in house using chemicals provided by another source and/or c) preparing or producing the core material and/or the surface material constituents in house using chemicals also produced or provided in house or at the location.

The core material and/or the surface material constituents may be combined by any suitable method known in the art or conventionally used, including melting the constituents and blending the molten constituents, processing the material constituents into shavings or pellets and combining the constituents by a mixing and pressure treating process, and the like.

In some embodiments, namely the monolithic or unibody target configurations the surface target component and the core backing component may comprise the same target material. However, there are contemplated monolithic or unibody target configurations and designs where there is a material gradient throughout the sputtering target and/or sputtering target assembly. A “material gradient”, as used herein, means that the sputtering target or sputtering target assembly comprises at least two of the materials contemplated herein, wherein the materials are located in the sputtering target in a gradient pattern. For example, a sputtering target or target assembly may comprise copper and titanium. The surface target material of this same target may comprise 90% copper and 10% titanium. If one viewed a cross-section of the target assembly or sputtering target, the amount or percentage of copper would decrease approaching the core backing component and the titanium percentage would increase approaching the core backing component. It is contemplated that the titanium percentage may decrease approaching the core backing material and the copper percentage may increase approaching the core backing component resulting in a 100% copper core backing component. A material gradient may be advantageous in order to detect wear of the target or to prepare subsequent layers that contain more or less of a certain component. It is also contemplated that a material gradient may comprise three or more constituents, depending on the needs of the layer, the component, the device and/or the vendor.

At least one surface area feature is coupled to or located in the back surface of the core backing component, wherein the surface area feature increases the effective surface area of the core backing component. The surface area feature comprises either a) a convex feature, a concave feature or a combination thereof; or b) an additive feature, a subtractive feature or a combination thereof.

As used herein, the phrases “convex feature”, “concave feature” or “a combination thereof” means that, in relation to each feature, that the feature is formed as part of the core backing component when the core backing component is itself formed. An example of these embodiments is where the core backing component is formed using a mold and the convex features, the concave features and/or the combination thereof of the features are part of the mold design. As used herein, the phrases “additive feature”, “subtractive feature” or “a combination thereof” mean that, in relation to each feature, that the feature is formed after the core backing component is formed. An example of these embodiments is where the core backing component is formed by any suitable method or apparatus and then the features are formed in or on the back surface or the coupling surface of the core backing component by a drill, a solder process or some other process or apparatus that can be used to either add (thus forming an additive feature) or subtract material (thus forming a subtractive feature) from the core backing component in a way so as to form the features.

As used herein, the phrases “additive feature”, “subtractive feature”, “convex feature” and “concave feature” are used to describe channels, microchannels, grooves, bumps and/or indentations can be produced in or on the core backing component of the sputtering target. The channels, microchannels, grooves, bumps, dimples, indentations or a combination thereof are primarily intended to increase the surface area of the back of the target. By placing the channels, microchannels, grooves, bumps, dimples, indentations or a combination thereof along the entire back surface of or the center of the backing component, the cooling efficiency of the method of cooling and cooling fluid is increased over conventional side cooling. The channels, microchannels, grooves, bumps, dimples, indentations or a combination thereof may also be placed in or on the coupling surface of the core backing component.

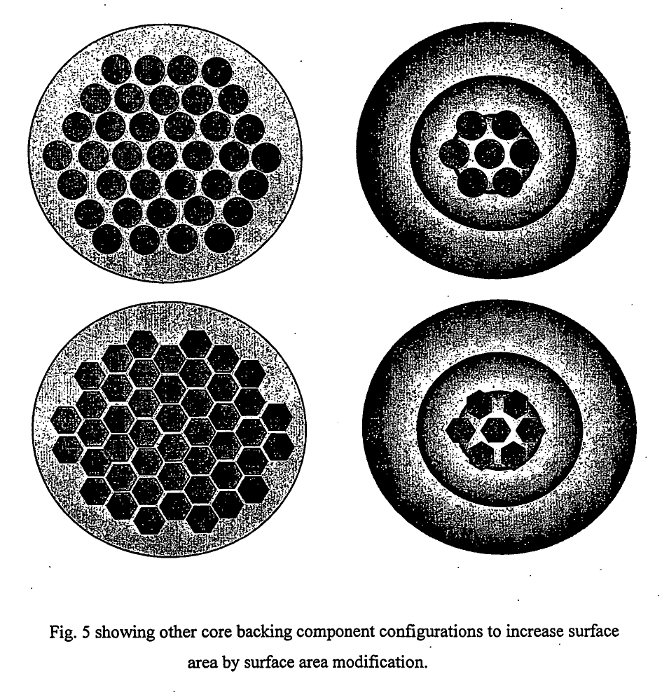

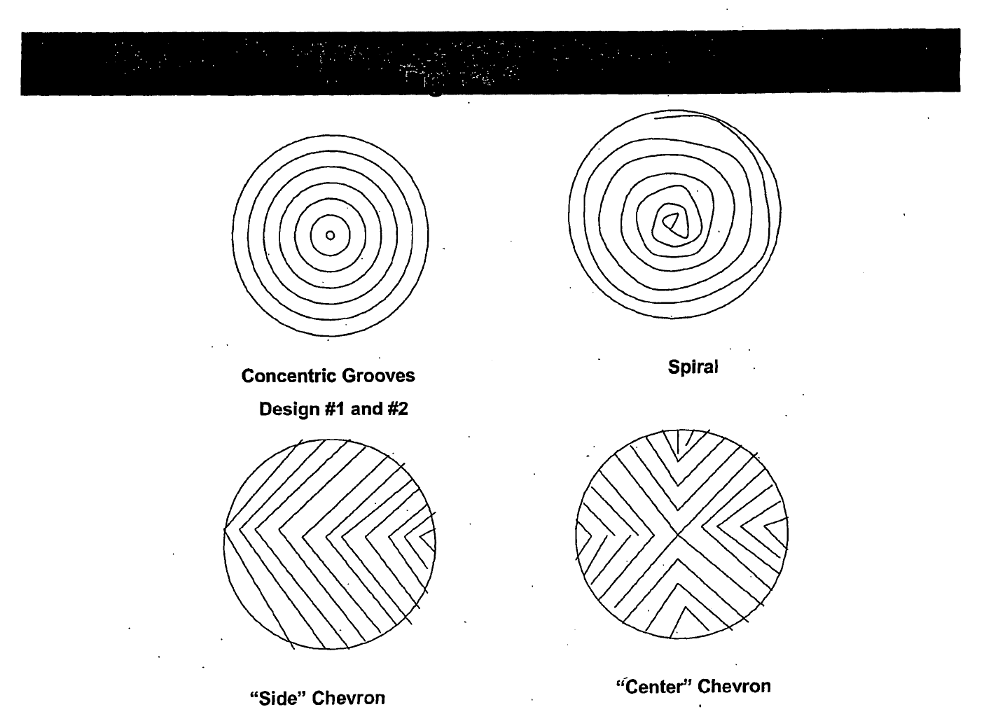

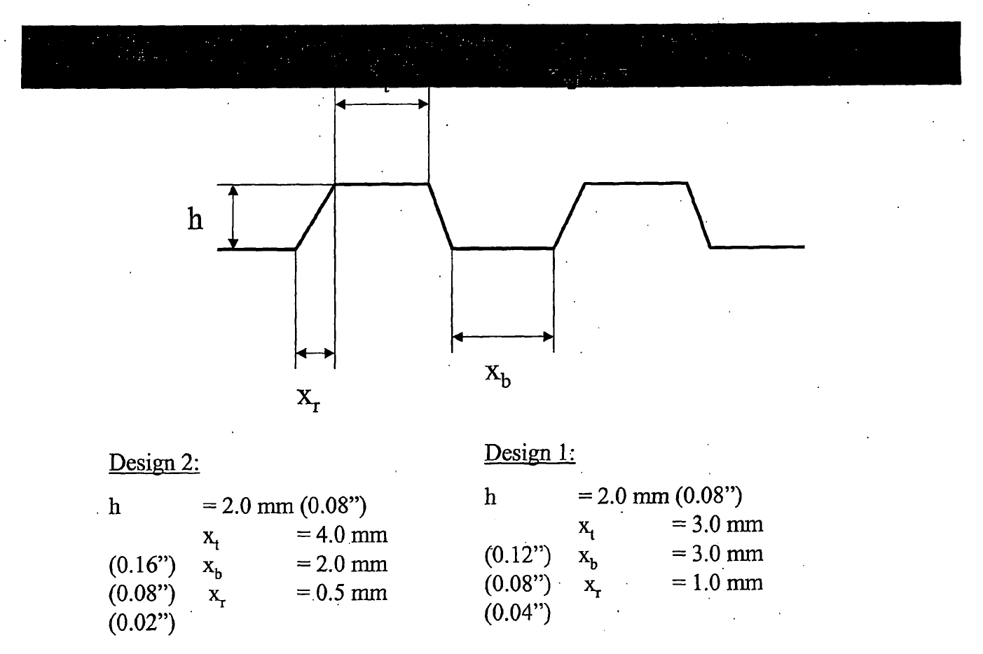

The channels, microchannels, grooves, bumps, dimples, indentations or a combination thereof can be arranged or formed in or on the core backing component in any suitable shape, including concentric circles or grooves, a spiral configuration, a “side” facing chevron or a “center” pointing chevron. Examples of several contemplated channels, microchannels, grooves, bumps, dimples, indentations or a combination thereof are shown in FIGS. 5 and 6, and a cross-section of a backing plate with channels, microchannels, grooves, bumps, dimples, indentations or a combination thereof is shown in FIG. 7 where two different groove/channel measurements are presented as Design 1 and Design 2. Other examples of groove patterns that can be formed in the core backing component are a cross-hatched pattern, linear grooves running across the backside of the plate or any groove, channel and/or microchannels configuration that effectively increases the surface area of the core backing component.

In other embodiments, bumps or other configurations formed from core backing component material or another comparable material can be “built up” on the back surface or coupling surface of the core backing component in order to effectively increase the surface area of the core backing component and/or sputtering target assembly. It is further contemplated that the material used to build up a pattern or formation on the back of the core backing component can not only increase the surface area of the backing plate, but may also work in conjunction with the cooling device/method to further enhance the cooling effect on the target and/or reduce unwanted deflection of atoms and/or molecules from the target surface component of the sputtering target assembly.

The channels, microchannels, grooves, bumps, dimples, indentations or a combination thereof can be formed on the core backing component by using any suitable method or device, including machining, LASERs and the like, as previously described, resulting in at least one additive feature, at least one subtractive feature or a combination thereof. The core backing component may also be molded originally to include the channels, microchannels, grooves, bumps, dimples, indentations or a combination thereof resulting in at least one convex feature, at least one concave feature or a combination thereof, depending on the machinery of the vendor and the needs of the customer using the target.

For electronic and semiconductor applications and components, such as components and materials that comprise a layer of conductive material, the cooling device utilized for a sputtering target or other similar type of component that is used to lay down or apply the conductive layer of material is placed adjacent to the core backing component of the sputtering target and/or sputtering target assembly. In contemplated embodiments, as mentioned earlier, the core backing component has channels, microchannels, grooves, bumps, dimples, indentations or a combination thereof formed in or on the coupling side or back side of the component and the cooling device or method not only contacts the core backing component, but also contacts the channels, microchannels, grooves, bumps, dimples, indentations or a combination thereof. If both the cooling enhancement method and/or device is being used in conjunction with the sensing/sensor device/method there will be channels located between the target and the backing plate for the sensing/sensor device and there will be channels, microchannels, grooves, bumps, dimples, indentations or a combination thereof formed in the backing plate that will increase the effective surface area of the backing plate of the target when in contact with a cooling fluid or cooling method. It should be appreciated, however, that the cooling enhancement method and/or device could be used alone without the sensing/sensor device and/or method.

In some embodiments, the incorporation of the channels, microchannels, grooves, bumps, dimples, indentations or a combination thereof will not only improve the cooling of the sputtering target and/or sputtering target assembly, but will also improve the cooling fluid flow along the core backing component. This improvement in cooling fluid flow can easily be attributed to and explained by conventional fluid mechanics principles.

The cooling fluid used in the cooling enhancement device and/or method may comprise any fluid that can be held at a particular temperature for the purpose of cooling a surface or can effect the cooling of a surface on contact. As used herein, the term “fluid” may comprise either a liquid or a gas. As used herein, any references to the term “gas” means that environment that contains pure gases, including nitrogen, helium, or argon, carbon dioxide, or mixed gases, including air. For the purposes of the present subject matter, any gas that is suitable to use in an electronic or semiconductor application is contemplated herein.

Contemplated sputtering targets described herein can be incorporated into any process or production design that produces, builds or otherwise modifies electronic, semiconductor and communication components. Electronic, semiconductor and communication components are generally thought to comprise any layered component that can be utilized in an electronic-based, semiconductor-based or communication-based product. Components described herein comprise semiconductor chips, circuit boards, chip packaging, separator sheets, dielectric components of circuit boards, printed-wiring boards, touch pads, wave guides, fiber optic and photon-transport and acoustic-wave-transport components, any materials made using or incorporating a dual damascene process, and other components of circuit boards, such as capacitors, inductors, and resistors.

Thin layers or films produced by the sputtering of atoms or molecules from targets discussed herein can be formed on any number or consistency of layers, including other metal layers, substrate layers, dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (polyarylene ether), such as those compounds disclosed in issued patents U.S. Pat. No. 5,959,157, U.S. Pat. No. 5,986,045, U.S. Pat. No. 6,124,421, U.S. Pat. 6,156,812, U.S. Pat. No. 6,172,128, U.S. Pat. No. 6,171,687, U.S. Pat. No. 6,214,746, and pending applications U.S. Ser. Nos. 09/197478, 09/538276, 09/544504, 09/741634, 09/651396, 09/545058, 09/587851, 09/618945, 09/619237, 09/792606, b) adamantane-based materials, such as those shown in pending application U.S. Ser. No. 09/545058; Serial PCT/US01/22204 filed Oct. 17, 2001; PCT/US01/50182 filed Dec. 31, 2001; 60/345374 filed Dec. 31, 2001; 60/347195 filed Jan. 8, 2002; and 60/350187 filed Jan. 15, 2002;, c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued patents U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending applications U.S. Ser. Nos. 09/046474, 09/046473, 09/111084, 09/360131, 09/378705, 09/234609, 09/379866, 09/141287, 09/379484, 09/392413, 09/549659, 09/488075, 09/566287, and 09/214219 all of which are incorporated by reference herein in their entirety and (e) Honeywell HOSP® organosiloxane.

The wafer or substrate may comprise any desirable substantially solid material. Particularly desirable substrates would comprise glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimides. In more preferred embodiments, the substrate comprises a material common in the packaging and circuit board industries such as silicon, copper, glass, or a polymer.

Substrate layers contemplated herein may also comprise at least two layers of materials. One layer of material comprising the substrate layer may include the substrate materials previously described. Other layers of material comprising the substrate layer may include layers of polymers, monomers, organic compounds, inorganic compounds, organometallic compounds, continuous layers and nanoporous layers.

The substrate layer may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer.

### EXAMPLES

### Example 1

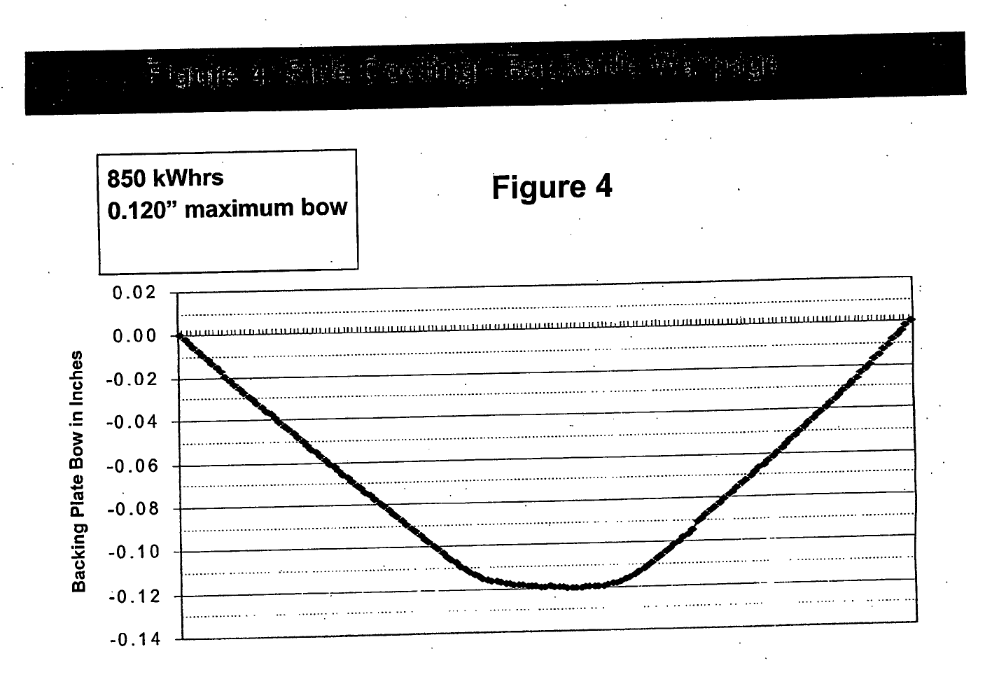

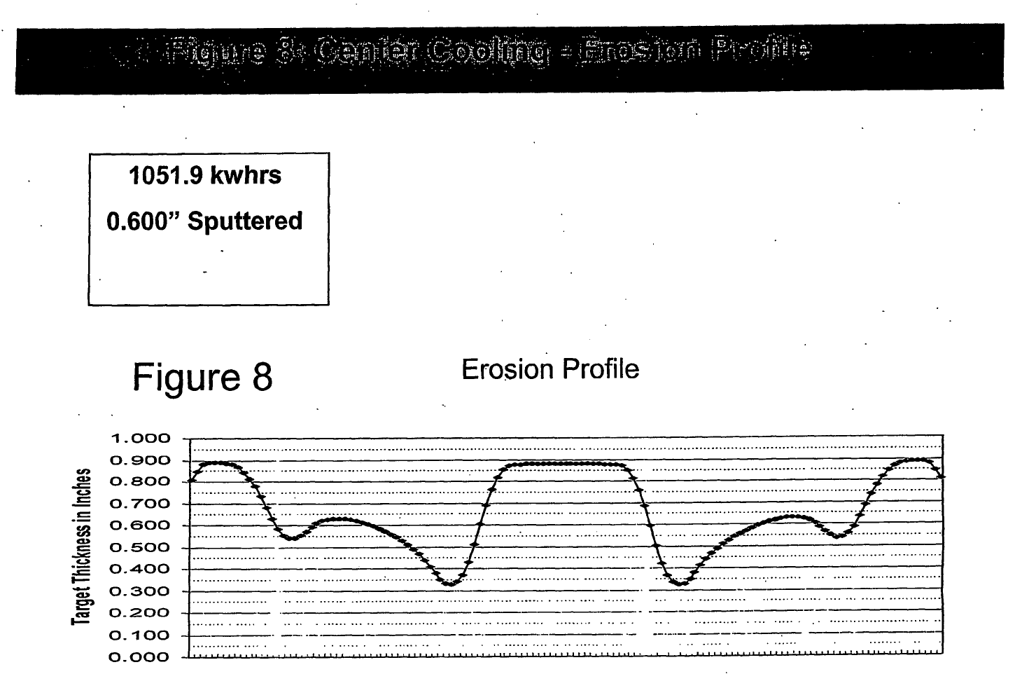

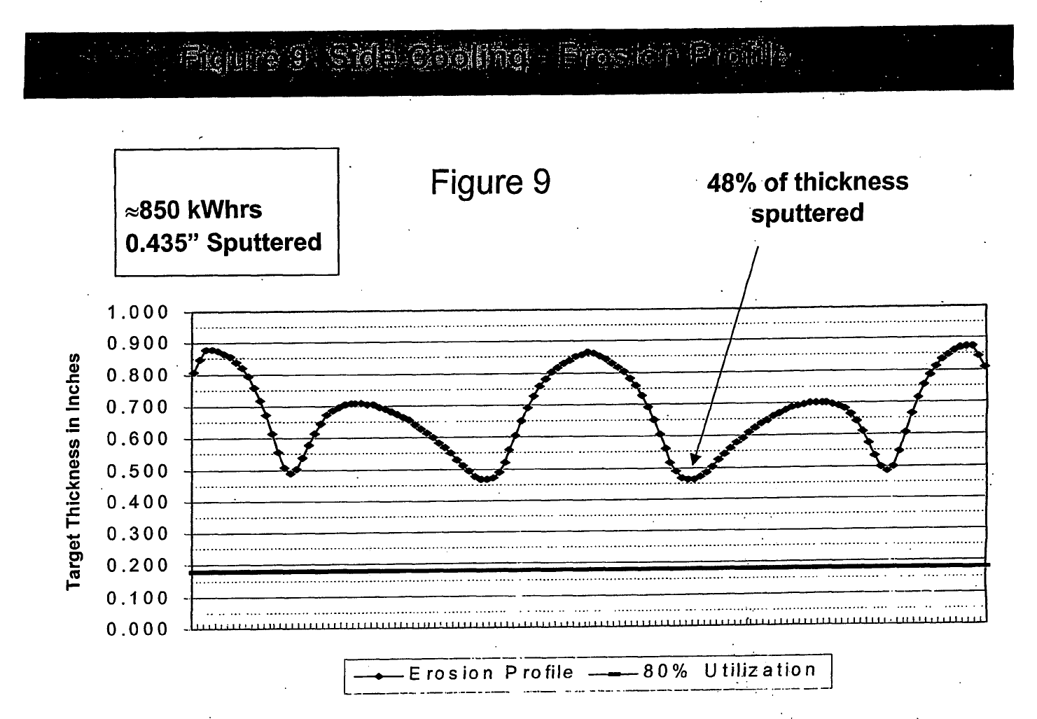

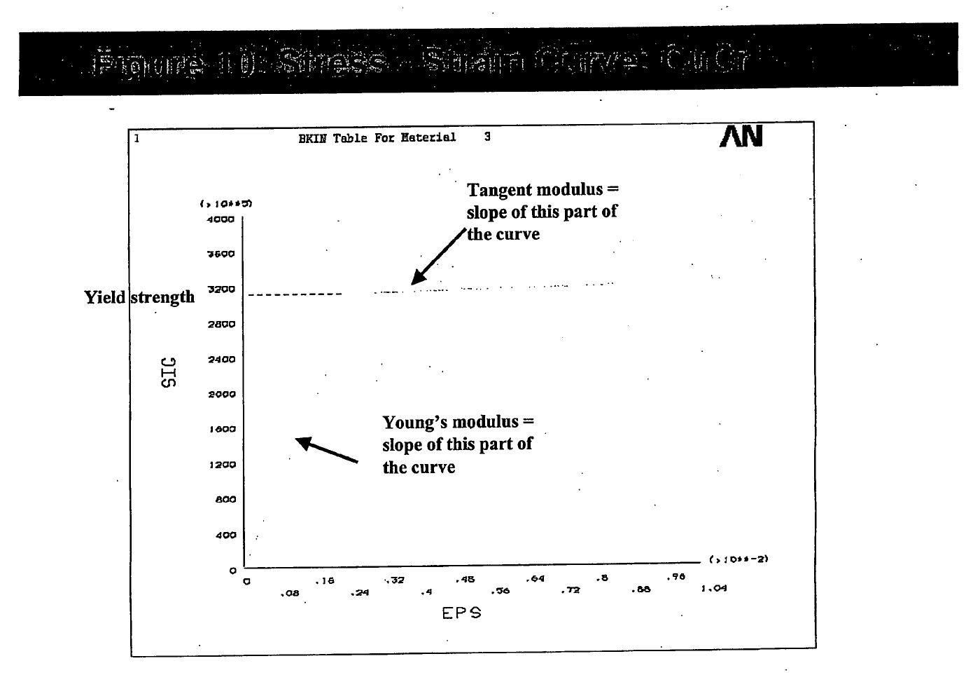

FIGS. 8 and 9 shows data collected from the high purity monolithic 200 mm Cu SIP target that is being utilized in the cooling enhancement experiments to follow. It should be appreciated that any sputtering target could be substituted in this set of experiments with the Cu SIP target. In FIG. 9, an erosion profile of a sputtering target sputtered at about 24 kW for a total of 850 kWhrs is shown. The sputtering tool in which this target was used had a side cooling design. FIG. 4 shows the profile of the backing plate bow of the target shown in FIG. 9. The maximum bow is about 3 mm.

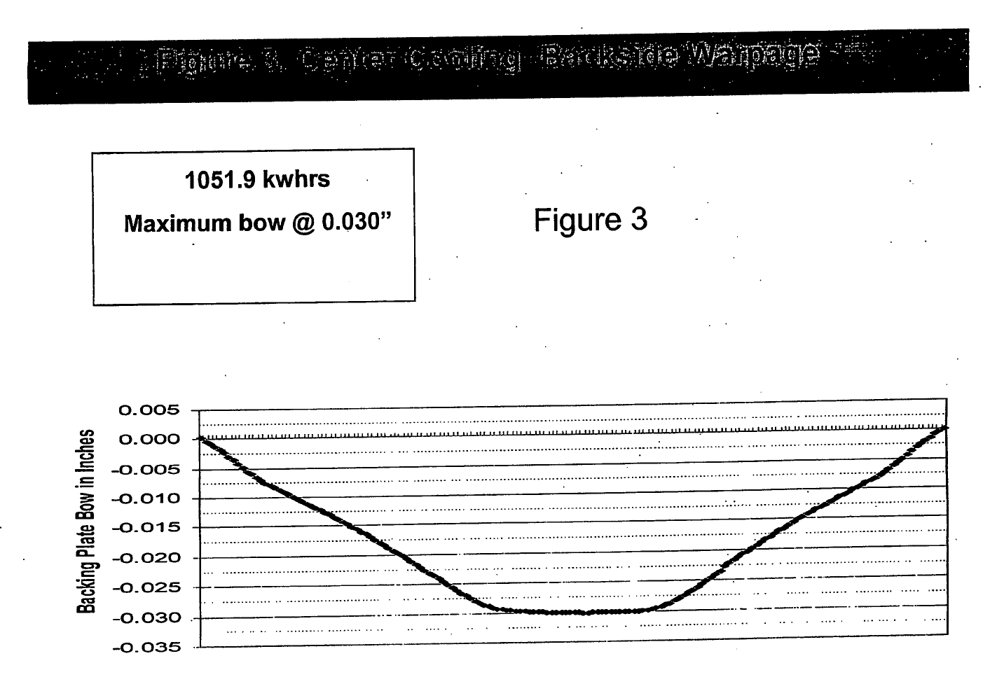

FIG. 8 shows an erosion profile of a sputtering target sputtered at about 40 kW for a total of 1050 kWhrs. The original target was identical to the one in FIG. 9. The difference in the profiles is due to this target being used in a sputtering tool with a center cooling design. FIG. 3 shows the profile of the backing plate bow of the target in FIG. 8. Even though this target has been sputtered at a higher sputtering power for more kWhrs, the maximum bow is only about 0.8 mm. The difference is attributed to the more efficient cooling design and illustrates the importance of target cooling.

### Example 2

This Example shows the estimation of deflection in a 200 mm Cu target comparing a Monolithic APEX/ECAE target arrangement and a Monolithic—Enhanced Cooling APEX/ECAE target arrangement.

The model is a finite element model with the following modeling parameters:
Power input: 24 kW total (proportional to erosion profile after about 850 kWhrs);
Heat transfer coefficient alpha: about 1500 W/m/K to about 5000 W/m/K (linear from center to O-ring groove);
4 gal/min water flow at inlet temperature of about 18° C.;
Pressure on core backing component is about 0.4 MPa (corresponds to about 3 atm water pressure +1 atm);
Bilinear kinematic yielding/hardening model;
Axisymmetric (2D) model; and

Target assembly clamped at outer edge of the assembly.

The details of the yield model are as follows:
VON MISES YIELD CRITERION:
yielding occurs when the equivalent Von Mises stress (s_{eqv}) is equal to the yield stress (s_{y}):
   s_{eqv}=[1/2{(s1−s2)²+(s1−s3)²+(s2−s3)²}]^{1/2}>s_{y}
KINEMATIC HARDENING RULE:
yield surface remains constant in size
yield surface translates in stress space when yielding occurs
DIRECTION OF FLOW:
associated flow rule (Prandtl-Reuss)
plastic strain normal to yield surface

For thermal stress calculations, the following materials were used at a reference temperature of 20° C.:

| | |
|---|---|
| APEX 40 micron | ECAE Cu |

| Density | 8900 | kg/m³ | 8900 | kg/m³ |
|---|---|---|---|---|
| Heat Capacity | 385 | J/kg/K | 385 | J/kg/K |
| Thermal Conductivity | 393 | W/m/K | 393 | W/m/K |
| Coefficient of | 1.66 × 10⁻⁵ 1/K | | 1.66 × 10⁻⁵ 1/K | |
| Thermal Expansion | | | | |
| Young's Modulus | 117 | GPa | 117 | GPa |
| Poisson's Ratio | 0.3 | | 0.3 | |
| Yield Strength | 95 | MPa | 115 | MPa |
| Tangent Modulus | 680 | MPa | 680 | MPa |

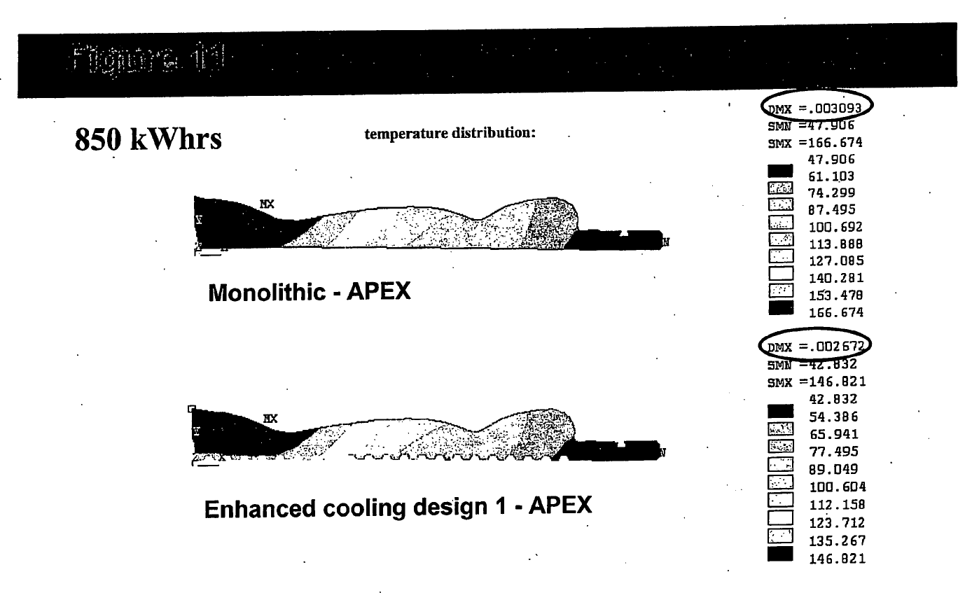

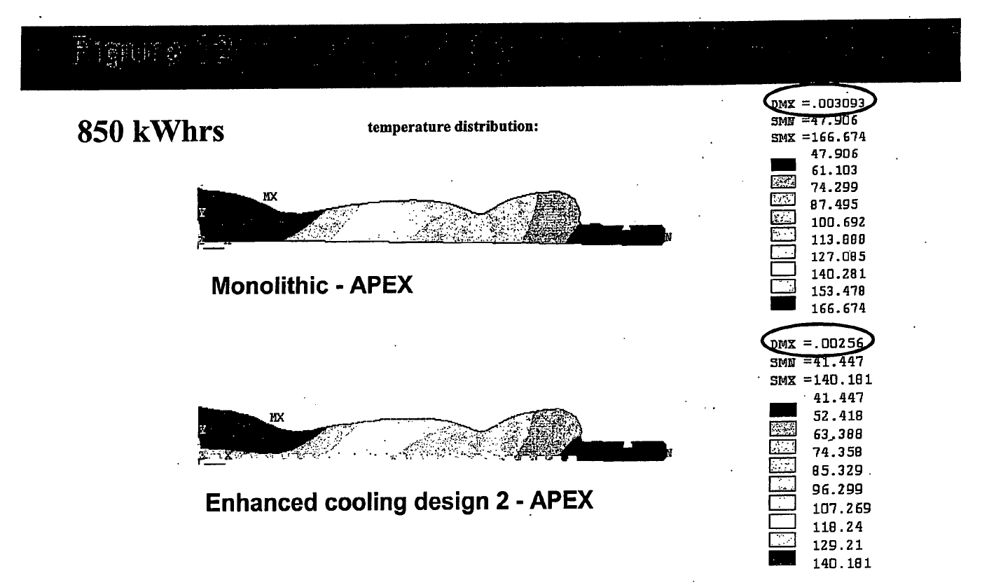

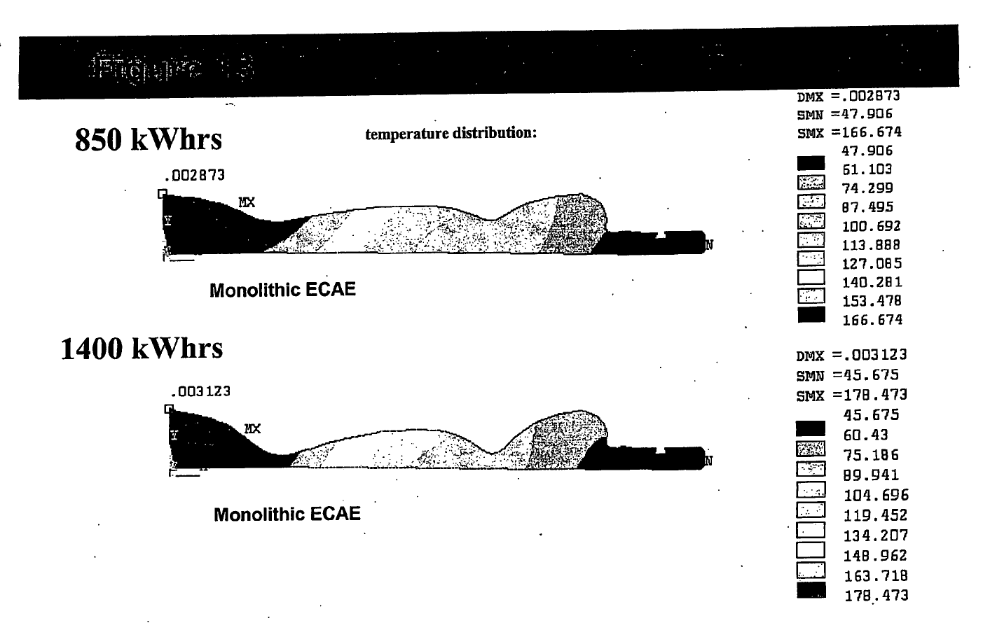

FIG. 10 shows an example of a Stress-Strain curve for a CuCr core backing component. FIGS. 11 and 12 show some of the results of this study, specifically the comparison of a conventional monolithic target with a monolithic target comprising at least some of the design goals disclosed herein. In FIG. 11, the new cooling design reduces the maximum target temperature by 20° C. and the deflection of the target by 14% (2.67 mm as compared to 3.09 mm). Also, the maximum deflection is near the center of the target. In FIG. 12, the new cooling design reduces the maximum target temperature by 26° C. and the deflection of the target by 17% (2.56 mm as compared to 3.09 mm). Also, the maximum deflection is near the center of the target.

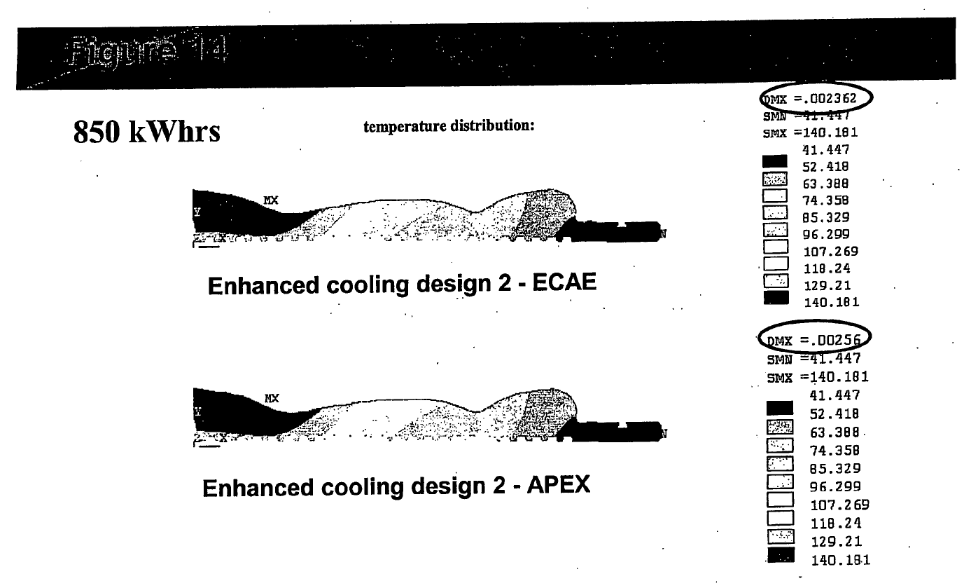

FIG. 13 shows a monolithic Cu ECAE target assembly at 850 kW hours and at 1400 kW hours. The maximum deflection of the Cu ECAE target assembly at 1400 kW hours is about the same as the APEX 40 micron monolithic assembly at 850 kW hours.

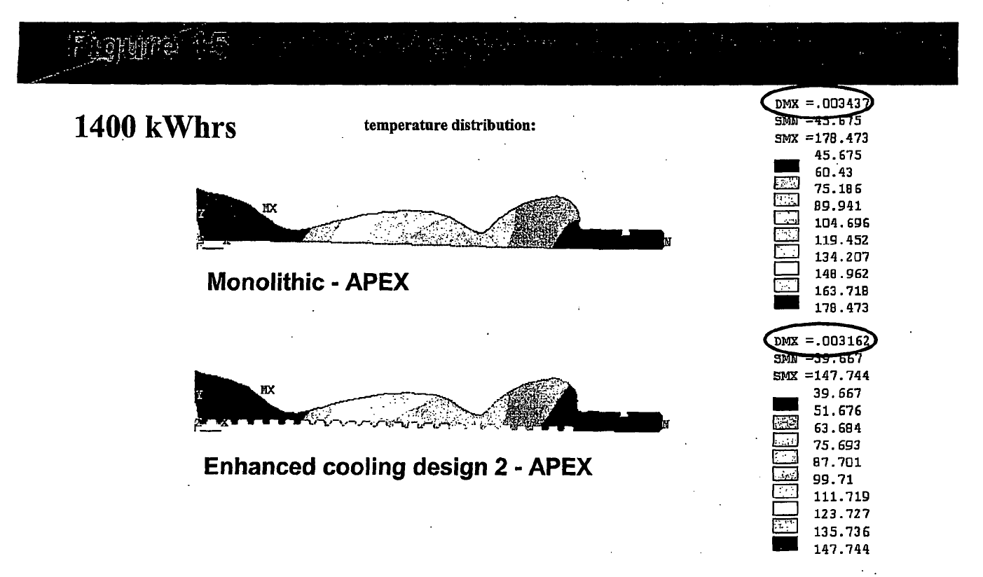

FIG. 14 shows a comparison of two of the contemplated designs—the ECAE Cu design versus the APEX design. Again, the maximum deflection is near the center of the target. Also, the change in design reduces the target deflection by an additional 6% (2.36 mm as compared to 2.56 mm).

FIG. 15 shows a late life comparison of the APEX 40 micron target assembly without a surface area modification and the APEX 40 micron target assembly with a surface area modification. The surface area modification reduces the maximum target temperature by about 30° C. and deflection by 8% (3.16 mm as comparedto 3.44 mm). Also, it was foundthat the structural stability of the target was not compromised by the “thinning” of the target.

Thus, specific embodiments and applications of sputtering targets and/or sputtering target assemblies comprising cooling enhancement methods and devices and methods of and devices for reducing wear and deflection in targets have been disclosed. It should be apparent, however, to those skilled in the art that many more modifications besides those already described are possible without departing from the inventive concepts herein. The inventive subject matter, therefore, including the claims is not to be restricted except in the spirit of the specification disclosed herein. Moreover, in interpreting the specification and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps maybe present, or utilized, or combined with other elements, components, or steps that are not expressly referenced.

We claim:

1. A sputtering target, comprising:
a target surface component comprising a target material;
a core backing component having a coupling surface and a back surface, wherein the coupling surface is coupled to the target surface component; and
at least one surface area feature coupled to or located in the back surface of the core backing component, wherein the surface area feature increases the effective surface area of the core backing component.

2. The sputtering target of claim 1, wherein the target material comprises a metal, a metal alloy or a combination thereof.

3. The sputtering target of claim 2, wherein the metal or metal alloy comprises a transition metal.

4. The sputtering target of claim 3, wherein the transition metal comprises copper, aluminum or titanium.

5. The sputtering target of claim 1, wherein the at least one surface area feature comprises at least one concave feature, at least one convex feature or a combination thereof.

6. The sputtering target of claim 5, wherein the at least one concave feature comprises at least one concentric indentation.

7. The sputtering target of claim 5, wherein the at least one concave feature comprises a dimple.

8. The sputtering target of claim 5, wherein the at least one concave feature comprises a plurality of linear channels.

9. The sputtering target of claim 5, wherein the at least one convex feature comprises a plurality of linear ridges or protrusions.

10. The sputtering target of claim 5, wherein the at least one convex feature comprises a bump.

11. The sputtering target of claim 5, wherein the at least one convex feature comprises at least one concentric ridge or protrusion.

12. A sputtering target, comprising:
a target surface component comprising a target material;
a core backing component having a coupling surface and a back surface, wherein the coupling surface is coupled to the target surface component; and
at least one surface area feature coupled to or located in the back surface of the core backing component, wherein the surface area feature comprises a subtractive feature, an additive feature or a combination thereof.

13. The sputtering target of claim 12, wherein the target material comprises a metal, a metal alloy or a combination thereof.

14. The sputtering target of claim 13, wherein the metal or metal alloy comprises a transition metal.

15. The sputtering target of claim 14, wherein the transition metal comprises copper, aluminum or titanium.

16. The sputtering target of claim 12, wherein the at least one subtractive feature comprises at least one concentric indentation.

17. The sputtering target of claim 12, wherein the at least one subtractive feature comprises a dimple.

18. The sputtering target of claim 12, wherein the at least one subtractive feature comprises a plurality of linear channels.

19. The sputtering target of claim 12, wherein the at least one additive feature comprises a plurality of linear ridges or protrusions.

20. The sputtering target of claim 12, wherein the at least one additive feature comprises a bump.

21. The sputtering target of claim 12, wherein the at least one additive feature comprises at least one concentric ridge or protrusion.

22. A method of forming a sputtering target, comprising:
providing a target surface component comprising a surface material;
providing a core backing component comprising a backing material and having a coupling surface and a back surface;
providing at least one surface area feature coupled to or located in the back surface of the core backing component, wherein the surface area feature increases the effective surface area of the core backing component; and
coupling the surface target component to the coupling surface of the core backing component.

23. A method of forming a sputtering target, comprising:
providing a target surface component comprising a surface material;
providing a core backing component comprising a backing material and having a coupling surface and a back surface;
providing at least one surface area feature coupled to or located in the coupling surface of the core backing component, wherein the surface area feature increases the effective surface area of the core backing component; and
coupling the surface target component to the coupling surface of the core backing component.

24. A sputtering target, comprising:
an integrated target surface component and core backing component, wherein the surface component and the backing component comprise the same target material; and
at least one surface area feature that is on or integrated into the core backing component, wherein the surface area feature increases the effective component of the core backing component.

25. The sputtering target of claim 24, wherein the target material comprises a metal, a metal alloy or a combination thereof.

26. The sputtering target of claim 25, wherein the metal or metal alloy comprises a transition metal.

27. The sputtering target of claim 26, wherein the transition metal comprises copper, aluminum or titanium.

28. The sputtering target of claim 24, wherein the at least one surface area feature comprises at least one concave feature, at least one convex feature or a combination thereof.

29. The sputtering target of claim 28, wherein the at least one concave feature comprises at least one concentric indentation.

30. The sputtering target of claim 28, wherein the at least one concave feature comprises a dimple.

31. The sputtering target of claim 28, wherein the at least one concave feature comprises a plurality of linear channels.

32. The sputtering target of claim 28, wherein the at least one convex feature comprises a plurality of linear ridges or protrusions.

33. The sputtering target of claim 28, wherein the at least one convex feature comprises a bump.

34. The sputtering target of claim 28, wherein the at least one convex feature comprises at least one concentric ridge or protrusion.

35. A sputtering target, comprising:
an integrated target surface component and core backing component, wherein the sputtering target comprises a target material gradient; and
at least one surface area feature that is located on or integrated into the core backing component, wherein the surface area feature increases the effective component of the core backing component.

36. The sputtering target of claim 35, wherein the target material comprises a metal, a metal alloy or a combination thereof.

37. The sputtering target of claim 36, wherein the metal or metal alloy comprises a transition metal.

38. The sputtering target of claim 37, wherein the transition metal comprises copper, aluminum or titanium.

39. The sputtering target of claim 35, wherein the at least one surface area feature comprises at least one concave feature, at least one convex feature or a combination thereof.

40. The sputtering target of claim 39, wherein the at least one concave feature comprises at least one concentric indentation.

41. The sputtering target of claim 39, wherein the at least one concave feature comprises a dimple.

42. The sputtering target of claim 39, wherein the at least one concave feature comprises a plurality of linear channels.

43. The sputtering target of claim 39, wherein the at least one convex feature comprises a plurality of linear ridges or protrusions.

44. The sputtering target of claim 39, wherein the at least one convex feature comprises a bump.

45. The sputtering target of claim 39, wherein the at least one convex feature comprises at least one concentric ridge or protrusion.
